(19) United States
(12) Patent Application Publication
(10) Pub. No.: US 2009/0130835 A1
(43) Pub. Date: May 21, 2009

(54) METHOD OF MANUFACTURING INVERTED T-SHAPED FLOATING GATE MEMORY

(75) Inventors: Erh-Kun LAI, Longjing Shiang (TW); Yen-Hao SHIH, Changhua City (TW); Ming-Hsiang HSUEH, Hsinchu City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: MACRONIX INTERNATIONAL CO., LTD., Hsinchu City (TW)

(21) Appl. No.: 11/941,813

(22) Filed: Nov. 16, 2007

(51) Int. Cl. H01L 21/336

(52) U.S. Cl. 438/594; 257/E21.422

(57) ABSTRACT

A memory device having a floating gate with a non-rectangular cross-section is disclosed. The non-rectangular cross-section may be an inverted T-shape, a U-shape, a trapezoid shape, or a double inverted T-shape. Methods are disclosed for producing a floating gate memory device having an improved coupling ratio due to an increased surface area of the floating gate. The memory device has a floating gate having a cross-sectional shape, such as an inverted T-shape, such that a top contour is a non-flat segment.

### TECHNICAL FIELD

The invention relates generally to a method of manufacturing memory devices and, more particularly, memory devices that may have an inverted T-shaped floating gate.

### BACKGROUND

Memory devices are devices for storing data and are usually implemented in the form of integrated circuitry. In contrast to volatile memory devices such as DRAM (dynamic random access memory), non-volatile memory devices are capable of retaining data in the absence of power supply. Given its nature, non-volatile memory devices are commonly used as memory cards or storage devices in portable electronic devices such as cell phones, MP3 players, digital still and video cameras, and other consumer electronics. As a result, the demand of non-volatile memories such as flash memories has grown exponentially in the past few years. As part of the growing demand, there are also demands and expectations for memory devices with low cost, low power consumption, and high performance or capacity, which have been driving the development of various memory designs.

Among different designs of memory devices, floating gate structures are one of the dominating non-volatile memory technologies. As an example, floating gate design structures typically use polysilicon floating gates to store charges, and a number of floating gates may be arranged in the form of memory arrays under the architectures of NAND flash and/or NOR flash memory. To program and erase a memory cell, charge tunneling techniques may be used to place charge carriers (i.e., electrons or holes) in the floating gate.

Without limiting the scope of the invention, floating gate transistors may be used in various devices and are commonly incorporated into non-volatile memory devices such as flash, EPROM, and EEPROM memory devices. For example, floating gate MOSFETs are commonly used in non-volatile memories. A floating gate MOSFET may include a MOSFET and one or more capacitors used to couple control voltages to the floating gate. A floating gate is a polysilicon gate insulated or surrounded by insulative materials such as SiO₂. The floating gate may store charge because it is completely surrounded by a high-quality insulator. The charge on the floating gate may be modified, for example, by applying voltages to the source, drain, and control gate terminals to effect Fowler-Nordheim tunneling and hot carrier injection. To maximize efficiency for this type of memory storage, it is desirable to have a high coupling ratio for floating gate memory devices.

### SUMMARY OF INVENTION

In one embodiment of the invention, a method for forming a non-volatile memory device is disclosed. A semiconductor substrate may be provided, and a first dielectric layer is formed over the semiconductor substrate. A first conductive layer is formed over the first dielectric layer. At least two trenches spaced apart from each other are provided by removing a portion of the first conductive layer, the first dielectric layer and the semiconductor substrate. The trenches extend down from the first conductive layer to the semiconductor substrate. A first insulating layer is formed within the trenches to fill the trenches. At least two insulating protrusions are provided by forming a first insulating layer within the trenches to fill the trenches with the first insulating layer protruding over a top surface of the first conductive layer. Sidewall insulators are formed along sidewalls of the insulating protrusions. A second conductive layer is formed over the first conductive layer to fill in a gap between the sidewall insulators to form an inverted T-shaped conductor. The inverted T-shape includes a portion of the first conductive layer and a portion of the second conductive layer.

In another embodiment of the invention, a method for forming a non-volatile memory device is disclosed. A semiconductor substrate may be provided, and a first dielectric layer is formed over the semiconductor substrate. A first conductive layer is formed over the first dielectric layer and a protective layer is formed over the first conductive layer. At least two trenches spaced apart from each other are provided by removing a portion of the protective layer, the first conductive layer, the first dielectric layer and the semiconductor substrate. The trenches extend down from the protective layer to the semiconductor substrate. A first insulating layer is formed within the trenches to fill the trenches. At least two insulating protrusions are provided by removing the protective layer with the first insulating layer protruding over a top surface of the first conductive layer. A second conductive layer is provided between the insulating protrusions and narrower than the underlying first conductive layer to form an inverted T-shaped conductor. The inverted T-shape includes a portion of the first conductive layer and a portion of the second conductive layer.

### BRIEF DESCRIPTION OF DRAWINGS

The foregoing summary, as well as the following detailed description, will be better understood when read in conjunction with the appended, exemplary drawings. It should be understood, however, that the invention is not limited to the precise arrangements and instrumentalities shown.

FIG. 1 illustrates an example of a floating gate transistor in the prior art.

FIG. 2 illustrates an exemplary non-volatile memory device structure having an inverted T-shaped floating gate consistent with embodiments of the invention.

FIGS. 3A-H illustrate an exemplary process for forming a non-volatile memory device consistent with embodiments of the invention.

### DETAILED DESCRIPTION

Reference will now be made in detail to the exemplary embodiments of the invention, examples of which are illustrated in the accompanying drawings. Wherever possible, the same reference numbers will be used throughout the drawings to refer to the same. The following examples disclose a memory device that uses a floating gate with a unique shape that provides a high coupling ratio for a floating gate structure. According to one example, the floating gate structure has an inverted T-shape, described in further detail below.

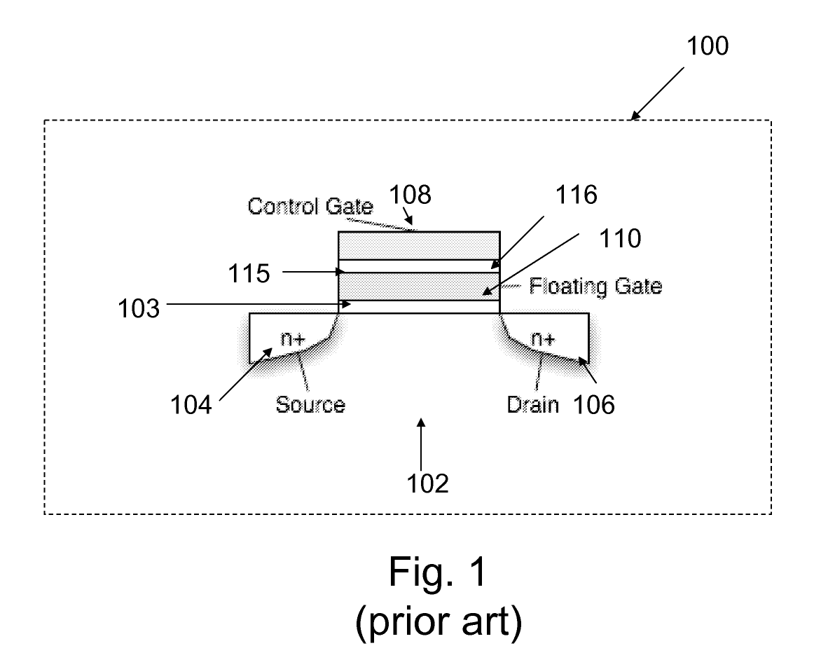

FIG. 1 illustrates a conventional floating gate transistor 100. Floating gate transistor 100 is formed on a substrate 102 and includes tunnel oxide layer 103, source 104, drain 106, control gate 108, and floating gate 110. Floating gate 110 has a cross-section that is rectangular in shape and has a top contour 115. A dielectric layer 116 is provided between floating gate 110 and control gate 108. In conventional floating gate transistor 100, the voltage VFG at the floating gate 110 may be governed by the following equation:

$${V}_{FG} = \frac{{C}_{gate}}{{C}_{total}} {V}_{G} + \frac{{C}_{source}}{{C}_{total}} {V}_{S} + \frac{{C}_{drain}}{{C}_{total}} {V}_{D} + \frac{{C}_{sub}}{{C}_{total}} {V}_{sub} \qquad ( 1 )$$

where Cgate and VG are the capacitance and voltage at the control gate 108, respectively, Csource and VS are the capacitance and voltage at the source 104, Cdrain and VD are the capacitance and voltage at the drain 106, and Csub and Vsub are the capacitance and voltage at the substrate 102. When substrate 102, source 104, and drain 106 are grounded, Eq. 1 reduces to the following:

$${V}_{FG} = \frac{{C}_{gate}}{{C}_{total}} {V}_{G} \qquad ( 2 )$$

The first term on the right hand side of Eq. 2 is known as the coupling ratio, and it is desirable to have a high coupling ratio, e.g., 0.6. The capacitance at the gate Cgate is given by the following relationship:

$${C}_{gate} = ɛ \frac{A}{d} \qquad ( 3 )$$

where ∉ is the dielectric constant, A is the surface area between the control gate 108 and the floating gate 110, and d is the distance between the control gate 108 and the floating gate 110. One can increase the coupling ratio by varying one or more of these three variables. In other words, increasing the dielectric constant, increasing the cross-sectional area, or decreasing the distance will result in a higher coupling ratio.

Embodiments of the present invention may increase the surface area by using an inverted T-shaped floating gate. For example, the surface area A between the control gate and the floating gate is determined by the length of the top contour of the floating gate. By changing the cross-sectional profile of the floating gate 110 from a rectangle to an inverted-T shape, the length of the top contour may be increased, and the surface area between the control gate 108 and the floating gate can be also be increased.

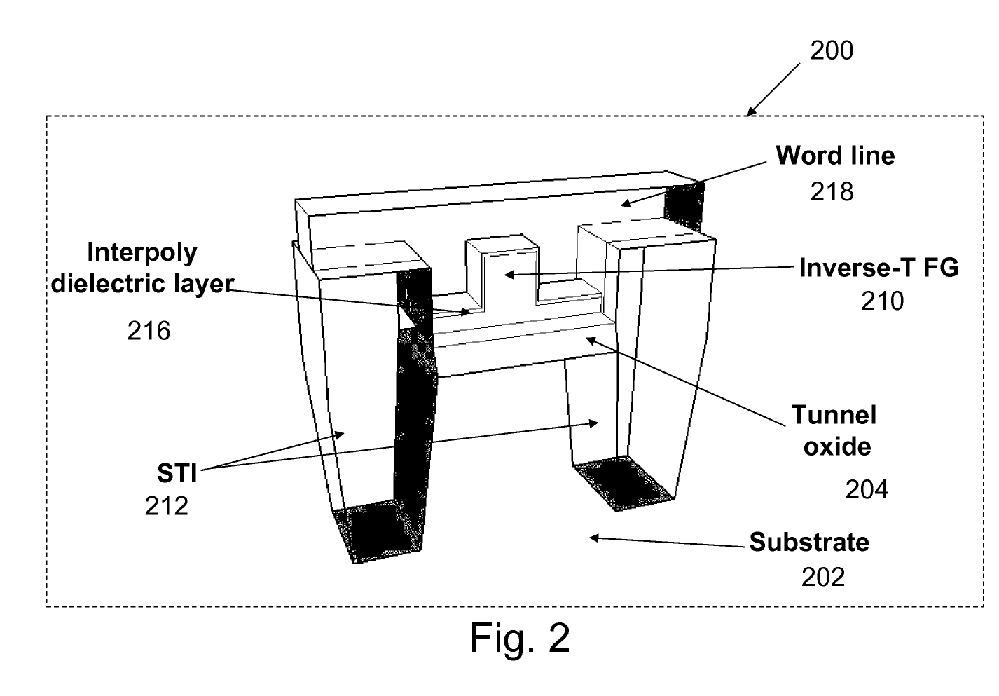

FIG. 2 illustrates an exemplary memory device structure having an inverted T-shaped floating gate consistent with examples of the present invention. As discussed above, the shape of the floating gate may provide an increased coupling ratio between the floating gate and the control gate. Non-volatile memory device structure 200 may include substrate 202, tunnel oxide layer 204, inverted T-shaped floating gate 210, shallow trench isolation (STI) structures 212, interpoly dielectric layer 216, and word line layer 218, which may function as a control gate. STI structures 212 effectively separate a plurality of memory cell regions. The inverted T-shaped floating gate 210 may have a top contour that would have a longer peripheral length as compared to a floating gate having a rectangular cross-section. In other words, there is more surface area with the inverted T-shape gate to increase the capacitance, thereby increasing the coupling ratio as compared to a device with a floating gate having a rectangular cross-section.

Alternatively, other cross-sectional shapes may be used for a floating gate to increase capacitance and the coupling ratio. Examples may include a U-shaped floating gate, a trapezoidal-shaped floating gate, and a double inverted T-shaped floating gate. In general, a floating gate having a cross-sectional profile such that the top contour is not a flat surface may be used to increase the coupling ratio. Although in this case, the top contour of the floating gate 210 forms an interface with the word line 218, other orientations between the floating gate 210 and the word line 218 may be used, so that the “top” contour may become the “bottom” contour or a “side” contour. Also, a plurality of memory cells having the non-volatile memory device structure 200 or similar structure may be arranged in one or more arrays to form a non-volatile memory device, with a plurality of word lines and bit lines (not shown) coupled to the floating gates and control gates of the individual memory cells.

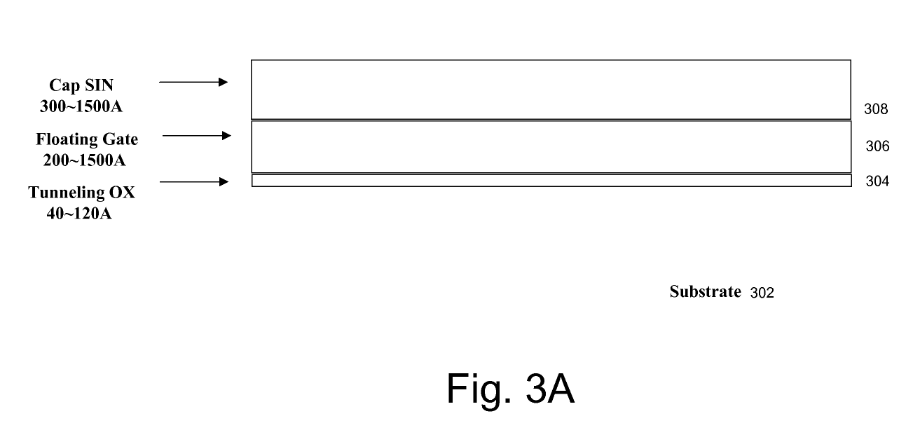

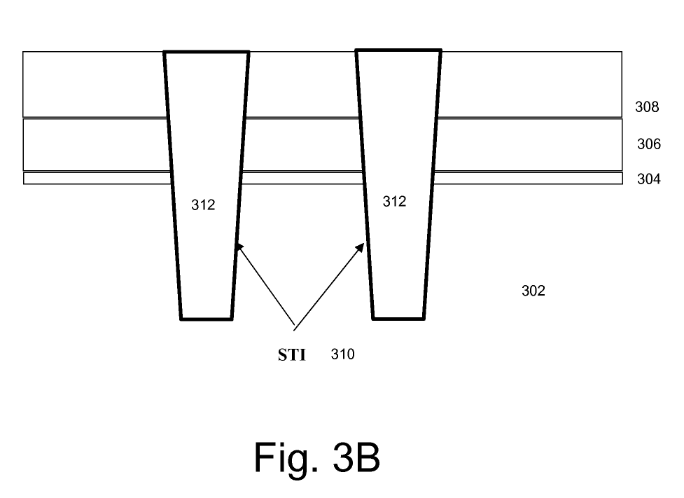

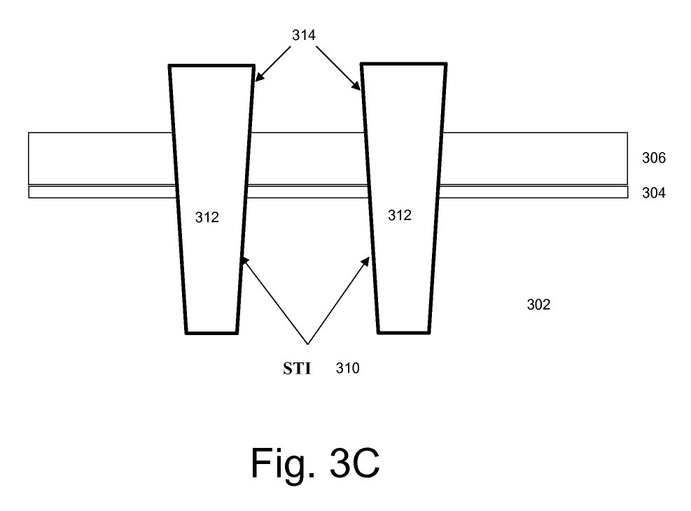

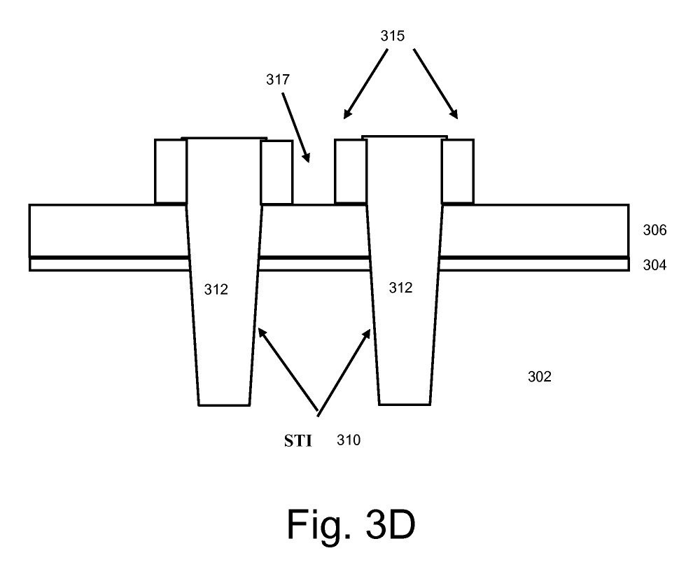

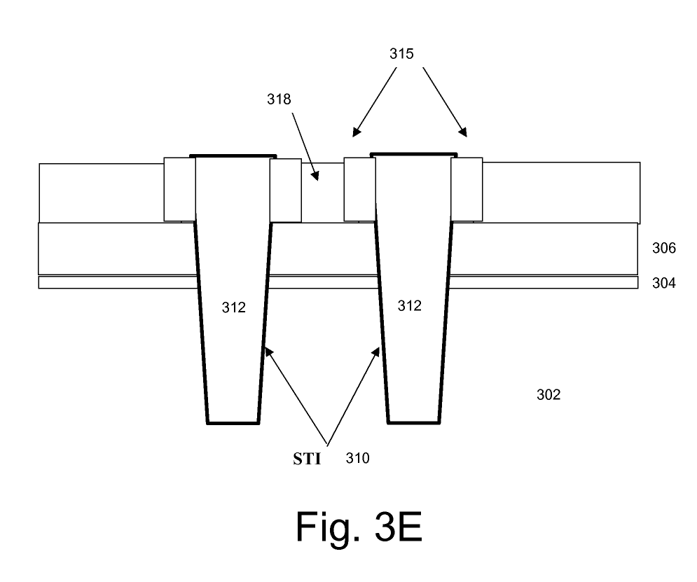

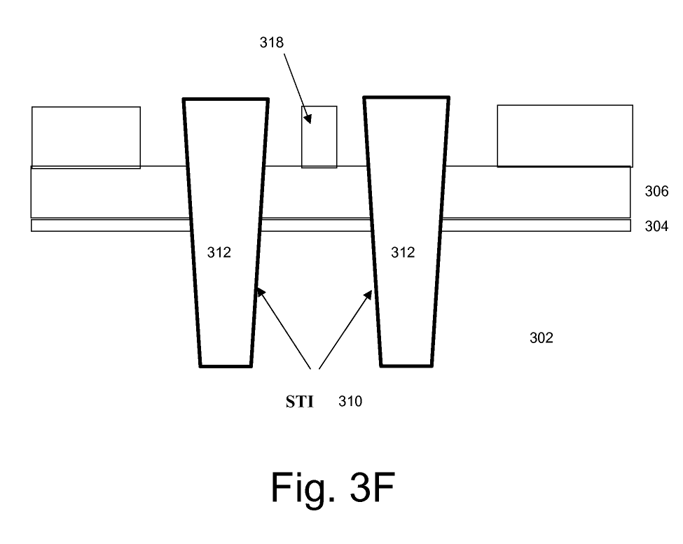

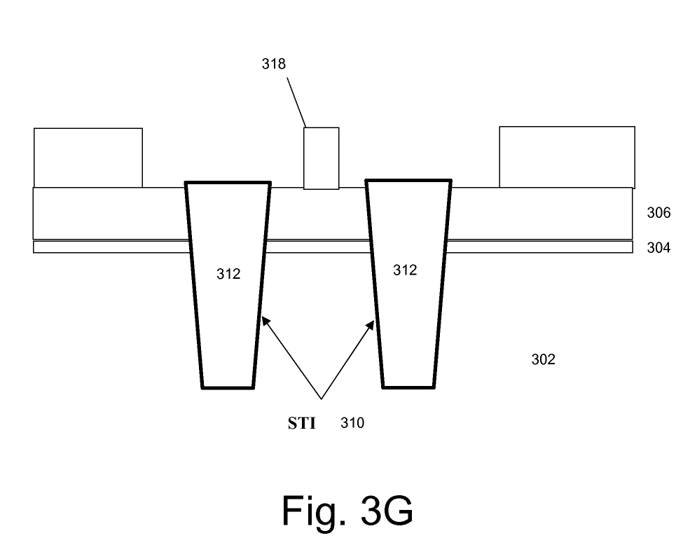

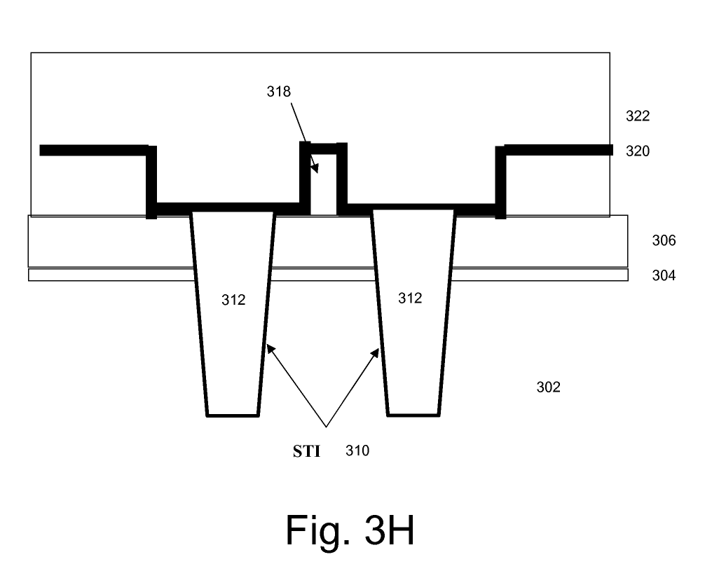

FIGS. 3A-H illustrate an exemplary process of forming a non-volatile memory device consistent with the embodiments of the invention. Referring to FIG. 3A, a semiconductor substrate 302 is provided, which preferably is a p-type silicon substrate. The semiconductor substrate 302 may be, for example, amorphous silicon. A first dielectric layer 304 is formed over the substrate 302. The first dielectric layer may be, for example, a tunnel silicon oxide layer. In one embodiment, the first dielectric layer 304 is about between 40 and 120 Angstroms. A first conductive layer 306, later to be formed into a portion of the floating gate, is formed over the first dielectric layer 304. The first conductive layer 304 may include polysilicon and, as an example, may have a thickness between approximately 200 and 1,500 Angstroms. In one example embodiment, a protective layer 308 may then be formed over the first conductive layer 306. The protective layer 308 may serve as a stopping layer for a chemical mechanical polishing (CMP) and may be a silicon nitride layer with a thickness between 300 to 1,500 Angstroms.

In FIG. 3B, trenches 310, which are used to effectively separate a plurality of memory cell regions and spaced apart from each other, are provided by removing a portion of the protective layer 308, the first conductive layer 306, the first dielectric layer 304 and the semiconductor substrate 302. The trenches 310 are extending from the protective layer 308 through the first conductive layer 306 and the first dielectric layer 304 to the semiconductor substrate 302. Subsequently, the trenches 310 are filled with a first insulating layer 312 (e.g. a silicon oxide layer) using either a high density plasma (HDP) deposition or by a spin on glass (SOG) technique, thus forming shallow trench isolation (STI) as shown in FIG. 3B. Then, in one example embodiment, the STI may be subject to the chemical-mechanical polishing (CMP) so that a portion of the first insulating layer 312 may be removed to expose the protective layer. As a result, a top surface of the first insulating layer 312 is aligned with a top surface of the protective layer 308.

Referring to FIG. 3C, insulating protrusions 314 are provided by removing the protective layer 308 with the first insulating layer 312 protruding over a top surface of the first conductive layer 306. In one example embodiment, the removal is accomplished by using a wet etch process with phosphoric acid (H₃PO₄). Alternatively, a dry etch process may be used.

A second insulating layer, for example, a silicon nitride layer, may be formed over the first conductive layer 306, which covers the first conductive layer 306 and over the top and exposed sidewalls of the insulating protrusions 314. In one example embodiment, a sidewall insulator etch process is performed on the second insulating layer to provide sidewall insulators 315, which are disposed along the sidewalls of the insulating protrusions 314, as shown in FIG. 3D, In one example embodiment, a portion of the second insulating layer, in other words, all of the second insulating layer except the sidewall insulators 315, may be removed from over the first conductive layer 306 to form a gap 317. In one example embodiment, the second insulating layer is etched by means of a wet etch process with phosphoric acid (H₃PO₄). A dry etch process may be used in other example embodiments.

Referring to FIG. 3E, a second conductive layer 318 (e.g., a polysilicon layer), later to constitute another portion of the floating gate, is formed over the first conductive layer 306 to fill in the gap 317 between the sidewall insulators 315. As a result, the second conductive layer 318 makes contact with the underlying first conductive layer 306 electrically. As shown in FIG. 3E, a portion of the second conductive layer 318 (i.e., in the gap 317 between sidewall insulators 315) in combination with a portion of the first conductive layer 306 between adjacent trenches 312, forms an inverted T-shaped conductor which may serve as a floating gate. In one example embodiment, the second conductive layer 318 may have a thickness between about 200 to 1500 Angstroms. The inverted T-shaped conductor may subsequently be subjected to an implantation with an N-type dopant such as arsenic (As).

In one embodiment, as shown in FIG. 3F, the sidewall insulators 315 may be removed using a wet etch. The sidewall insulators 315, for example, may include silicon nitride. Accordingly, a wet etch process with phosphoric acid (H₃PO₄) is used to easily strip the sidewall insulators 315, leaving the first conductive layer 306, the second conductive layer 318 and the first insulating layer 312 free of any defects.

The insulating protrusions 314 filled with the first insulating layer 312, referring back to FIG. 3C, are protruding over the top surface of the first conductive layer 306. The insulating protrusions may optionally be removed by applying a wet etch with hydrogen fluoride (HF). As a result, the first insulating layer 312 may be aligned with the first conductive layer 306 as illustrated in FIG. 3G.

In FIG. 3H, a second dielectric layer 320 is formed over the contours of the inverted T-shaped conductor and the top surface of the insulating protrusions 314. In one embodiment, the second dielectric layer 320 is a tri-layer structure. The tri-layer structure may include, for example, a first silicon oxide layer, a silicon nitride layer formed over the first silicon oxide layer, and a second silicon oxide layer formed over the silicon nitride layer (silicon oxide-silicon nitride-silicon oxide layer). Then a third conductive layer 322, which may serve as control gates, may be formed over the second dielectric layer 320. The third conductive layer 322 may be patterned to form word lines of the memory device.

Referring to FIG. 3H, it is apparent that the surface area A between the control gate (the third conductive layer 322) and the floating gate (the inverted T-shaped conductor) is increased by increasing the peripheral length of the contour of the inverted T-shape floating gate. Thus the capacitance at the floating gate Cgate is increased based on the equation

$${C}_{gate} = ɛ \frac{A}{d}$$

obtaining a higher coupling ratio, which result in a more efficient program operation.

It will be appreciated by those skilled in the art that changes could be made to the examples described above without departing from the broad inventive concept thereof. It is understood, therefore, that this invention is not limited to the particular examples disclosed, but it is intended to cover modifications within the spirit and scope of the present invention as defined by the appended claims.

1. A method for forming a semiconductor device having a memory device, the method comprising:
providing a semiconductor substrate;
forming a first dielectric layer over the substrate;
forming a first conductive layer over the first dielectric layer;
removing a portion of the first conductive layer, the first dielectric layer, and the semiconductor substrate to provide at least two trenches spaced apart from each other and extending from the first conductive layer to the semiconductor substrate;
forming a first insulating layer within the trenches to fill the trenches and protrude over a top surface of the first conductive layer to provide at least two insulating protrusions;
forming sidewall insulators along sidewalls of the insulating protrusions; and
forming a second conductive layer over the first conductive layer to fill in a gap between the sidewall insulators to form an inverted T-shaped conductor, the inverted T-shaped conductor including a portion of the first conductive layer and a portion of the second conductive layer.

2. The method of claim 1, wherein forming the two insulating protrusions comprises:
providing a protective layer over the first conductive layer;
removing a portion of the protective layer when removing the portion of the first conductive layer, the first dielectric layer, and the semiconductor substrate to provide the two trenches that also extend through the protective layer;
forming the first insulating layer within the trenches to fill the trenches; and
removing the protective layer with the first insulating layer protruding over a top surface of the first conductive layer to provide the two insulating protrusions.

3. The method of claim 2, wherein the protective layer comprises silicon nitride.

4. The method of claim 2, wherein the protective layer is removed by a wet etch process.

5. The method of claim 1, wherein the first dielectric layer comprises tunneling silicon oxide and the first insulating layer comprises silicon oxide.

6. The method of claim 1, wherein the sidewall insulators comprise silicon nitride.

7. The method of claim 1, wherein at least one of the first conductive layer and the second conductive layer comprises polysilicon.

8. The method of claim 1, further comprising removing the sidewall insulators after the inverted T-shaped conductor is formed.

9. The method of claim 8, further comprising forming a second dielectric layer over the inverted T-shaped conductor and the first insulating layer.

10. The method of claim 9, wherein the second dielectric layer comprises a tri-layer structure of a first silicon oxide layer, a silicon nitride layer over the first silicon oxide layer, and a second silicon oxide layer over the silicon nitride layer.

11. The method of claim 8, further comprising forming a third conductive layer over the second dielectric layer and etching the third conductive layer to form a control gate.

12. A method for forming a semiconductor device having a non-volatile memory device, the method comprising:
providing a semiconductor substrate;
forming a first dielectric layer over the substrate;
forming a first conductive layer over the first dielectric layer;
providing a protective layer over the first conductive layer;
removing a portion of the protective layer, the first conductive layer, the first dielectric layer, and the semiconductor substrate to provide at least two trenches spaced apart from each other and extending from the protective layer to the semiconductor substrate;
forming a first insulating layer within the trenches to fill the trenches;
removing the protective layer with the first insulating layer protruding over a top surface of the first conductive layer to provide at least two insulating protrusions; and
providing a second conductive structure between the insulating protrusions and narrower than the underlying first conductive layer to form an inverted T-shaped conductor, the inverted T-shaped conductor including a portion of the first conductive layer and a portion of the second conductive layer.

13. The method of claim 12, wherein providing the second conductive structure comprises:
forming sidewall insulators along sidewalls of the insulating protrusions; and
forming a second conductive layer over the first conductive layer to provide the second conductive layer in a gap between the sidewall insulators.

14. The method of claim 12, wherein forming the first insulating layer within the trenches comprises:
forming the first insulating layer over the substrate to fill the trenches and over the protective layer; and
removing a portion of the first insulating layer to expose the protective layer and to substantially align a top surface of the first insulating layer with a top surface of the protective layer.

15. The method of claim 13, wherein forming the sidewall insulators along the sidewalls of the insulating protrusions comprises:
forming a second insulating layer over the first conductive layer and the insulating protrusions; and
removing a portion of the second insulating layer to provide sidewall insulators along the sidewalls of the insulating protrusions.

16. The method of claim 13, wherein the sidewall insulators comprise silicon nitride.

17. The method of claim 13, further comprising removing the sidewall insulators after the second conductive layer is provided in the gap between the sidewall insulators.

18. The method of claim 12, wherein the first dielectric layer comprises tunneling silicon oxide and the first insulating layer comprises silicon oxide.

19. The method of claim 12, wherein at least one of the first conductive layer and the second conductive layer comprises polysilicon.

20. The method of claim 12 further comprising forming a second dielectric layer over the inverted T-shaped conductor and the first insulating layer.

21. The method of claim 20, wherein the second dielectric layer comprises a tri-layer structure of a first silicon oxide layer, a silicon nitride layer over the first silicon oxide layer, and a second silicon oxide layer over the silicon nitride layer.

22. The method of claim 20, further comprising forming a third conductive layer over the second dielectric layer and etching the third conductive layer to form a control gate.
